(19) United States
(12) Patent Application Publication
(10) Pub. No.: US 2014/0373742 A1
(43) Pub. Date: Dec. 25, 2014

(54) METHOD OF MANUFACTURING A HIGH-RESOLUTION FLEXOGRAPHIC PRINTING PLATE

(71) Applicant: Ed S. Ramakrishnan, Spring, TX (US)

(72) Inventor: Ed S. Ramakrishnan, Spring, TX (US)

(73) Assignee: UNI-PIXEL DISPLAYS, INC., The Woodlands, TX (US)

(21) Appl. No.: 13/924,930

(22) Filed: Jun. 24, 2013

(51) Int. Cl. G03F 7/20; B41N 1/12

(52) U.S. Cl. CPC G03F 7/2032; B41N 1/12
USPC 101/375; 430/309

(57) ABSTRACT

A method of manufacturing a high-resolution flexographic printing plate includes exposing a back side of a flexographic printing plate substrate to a first UV radiation. A top side of the flexographic printing plate substrate is exposed to a second UV radiation through a photomask that includes a patterned design. The flexographic printing plate substrate is developed. The flexographic printing plate substrate is cured. A flexographic printing system includes an ink roll, an anilox roll, a printing plate cylinder, a high-resolution flexographic printing plate disposed on the printing plate cylinder, and an impression cylinder. The flexographic printing plate includes embossing patterns corresponding to a patterned design. The embossing patterns are patterned into the flexographic printing plate using a photomask.

### BACKGROUND OF THE INVENTION

An electronic device with a touch screen allows a user to control the device by touch. The user may interact directly with the objects depicted on a display by touch or gestures. Touch screens are commonly found in consumer, commercial, and industrial devices including smartphones, tablets, laptop computers, desktop computers, monitors, portable gaming devices, gaming consoles, and televisions.

A touch screen includes a touch sensor that includes a pattern of conductive lines disposed on a substrate. Flexographic printing is a rotary relief printing process that transfers an image to a substrate. A flexographic printing process may be adapted for use in the manufacture of touch sensors.

### BRIEF SUMMARY OF THE INVENTION

According to one aspect of one or more embodiments of the present invention, a method of manufacturing a high-resolution flexographic printing plate includes exposing a back side of a flexographic printing plate substrate to a first UV radiation. A top side of the flexographic printing plate substrate is exposed to a second UV radiation through a photomask that includes a patterned design. The flexographic printing plate substrate is developed. The flexographic printing plate substrate is cured.

According to one aspect of one or more embodiments of the present invention, a flexographic printing system includes an ink roll, an anilox roll, a printing plate cylinder, a high-resolution flexographic printing plate disposed on the printing plate cylinder, and an impression cylinder. The flexographic printing plate includes embossing patterns corresponding to a patterned design. The embossing patterns are patterned into the flexographic printing plate using a photomask.

Other aspects of the present invention will be apparent from the following description and claims.

### BRIEF DESCRIPTION OF THE DRAWINGS

FIG. 1 shows a portion of a conductive pattern design on a flexible and transparent substrate in accordance with one or more embodiments of the present invention.

FIG. 2 shows a flexographic printing system in accordance with one or more embodiments of the present invention.

FIG. 3 shows a method of manufacturing a conventional flexographic printing plate.

FIG. 4 shows a top-view of a photomask in accordance with one or more embodiments of the present invention.

FIG. 5 shows a method of manufacturing a high-resolution flexographic printing plate with the photomask in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

A conventional flexographic printing system uses a flexographic printing plate, sometimes referred to as a flexomaster, to transfer an image to a substrate. The flexographic printing plate includes one or more embossing patterns, or raised projections, that have distal ends onto which ink or other material may be deposited. In operation, the inked flexographic printing plate transfers an ink image of the one or more embossing patterns to the substrate. The ability of a conventional flexographic printing system to print lines is limited by the resolution of the conventional flexographic printing plate made using a thermal imaging layer process.

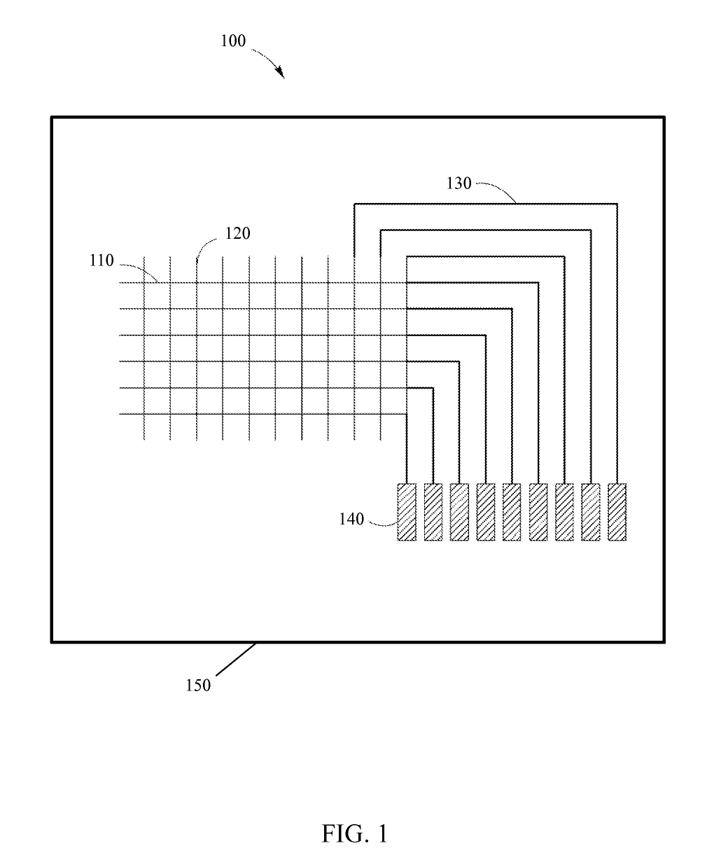

FIG. 1 shows a portion of a conductive pattern design on a flexible and transparent substrate in accordance with one or more embodiments of the present invention. Two or more conductive pattern designs 100 may form a projected capacitance touch sensor (not independently illustrated). In certain embodiments, conductive pattern design 100 may include a micro-mesh formed by a plurality of parallel x-axis conductive lines 110 and a plurality of parallel y-axis conductive lines 120 disposed on substrate 150. X-axis conductive lines 110 may be perpendicular or angled relative to y-axis conductive lines 120. A plurality of interconnect conductive lines 130 may route x-axis conductive lines 110 and y-axis conductive lines 120 to connector conductive lines 140. A plurality of connector conductive lines 140 may be configured to provide a connection to an interface (not shown) to a touch sensor controller (not shown) that detects touch through the touch sensor (not shown).

In certain embodiments, one or more of x-axis conductive lines 110, y-axis conductive lines 120, interconnect conductive lines 130, and connector conductive lines 140 may have different line widths or different orientations. The number of x-axis conductive lines 110, the line-to-line spacing between x-axis conductive lines 110, the number of y-axis conductive lines 120, and the line-to-line spacing between y-axis conductive lines 120 may vary based on an application. One of ordinary skill in the art will recognize that the size, configuration, and design of conductive pattern design 100 may vary in accordance with one or more embodiments of the present invention.

In one or more embodiments of the present invention, one or more of x-axis conductive lines 110 and one or more of y-axis conductive lines 120 may have a line width less than approximately 10 micrometers. In one or more embodiments of the present invention, one or more of x-axis conductive lines 110 and one or more of y-axis conductive lines 120 may have a line width in a range between approximately 10 micrometers and approximately 50 micrometers. In one or more embodiments of the present invention, one or more of x-axis conductive lines 110 and one or more of y-axis conductive lines 120 may have a line width greater than approximately 50 micrometers. One of ordinary skill in the art will recognize that the shape and width of one or more x-axis conductive lines 110 and one or more y-axis conductive lines 120 may vary in accordance with one or more embodiments of the present invention.

In one or more embodiments of the present invention, one or more of interconnect conductive lines 130 may have a line width in a range between approximately 50 micrometers and approximately 100 micrometers. One of ordinary skill in the art will recognize that the shape and width of one or more interconnect conductive lines 130 may vary in accordance with one or more embodiments of the present invention. In one or more embodiments of the present invention, one or more of connector conductive lines 140 may have a line width greater than approximately 100 micrometers. One of ordinary skill in the art will recognize that the shape and width of one or more connector conductive lines 140 may vary in accordance with one or more embodiments of the present invention.

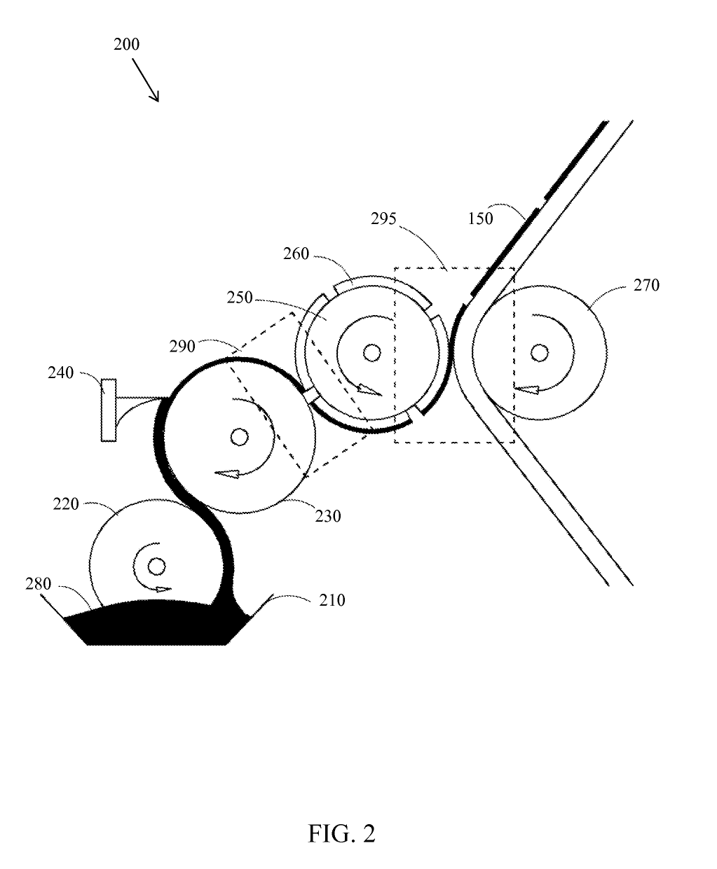

FIG. 2 shows a flexographic printing system in accordance with one or more embodiments of the present invention. Flexographic printing system 200 may include an ink pan 210, an ink roll 220 (also referred to as a fountain roll), an anilox roll 230 (also referred to as a meter roll), a doctor blade 240, a printing plate cylinder 250, a high-resolution flexographic printing plate 260, and an impression cylinder 270.

In operation, ink roll 220 transfers ink 280 from ink pan 210 to anilox roll 230. In certain embodiments, ink 280 may be a catalytic ink or catalytic alloy ink that serves as a plating seed suitable for metallization by electroless plating. In other embodiments, ink 280 may be an opaque ink or other opaque material suitable for flexographic printing. One of ordinary skill in the art will recognize that the composition of ink 280 may vary in accordance with one or more embodiments of the present invention. Anilox roll 230 is typically constructed of a steel or aluminum core that may be coated by an industrial ceramic whose surface contains a plurality of very fine dimples, known as cells (not shown). Doctor blade 240 removes excess ink 280 from anilox roll 230. In transfer area 290, anilox roll 230 meters the amount of ink 280 transferred to flexographic printing plate 260 to a uniform thickness. Printing plate cylinder 250 may be generally made of metal and the surface may be plated with chromium, or the like, to provide increased abrasion resistance. Flexographic printing plate 260 may be mounted to printing plate cylinder 250 by an adhesive (not shown).

One or more substrates 150 move between printing plate cylinder 250 and impression cylinder 270. In one or more embodiments of the present invention, substrate 150 may be transparent. Transparent means the transmission of visible light with a transmittance rate of 85% or more. In one or more embodiments of the present invention, substrate 150 may be polyethylene terephthalate (“PET”), polyethylene naphthalate (“PEN”), cellulose acetate (“TAC”), linear low-density polyethylene (“LLDPE”), bi-axially-oriented polypropylene (“BOPP”), polyester, polypropylene, or glass. One of ordinary skill in the art will recognize that the composition of substrate 150 may vary in accordance with one or more embodiments of the present invention. Impression cylinder 270 applies pressure to printing plate cylinder 250, transferring an image from embossing patterns of flexographic printing plate 260 onto substrate 150 at transfer area 295. The rotational speed of printing plate cylinder 250 is synchronized to match the speed at which substrate 285 moves through flexographic printing system 200. The speed may vary between 20 feet per minute to 750 feet per minute.

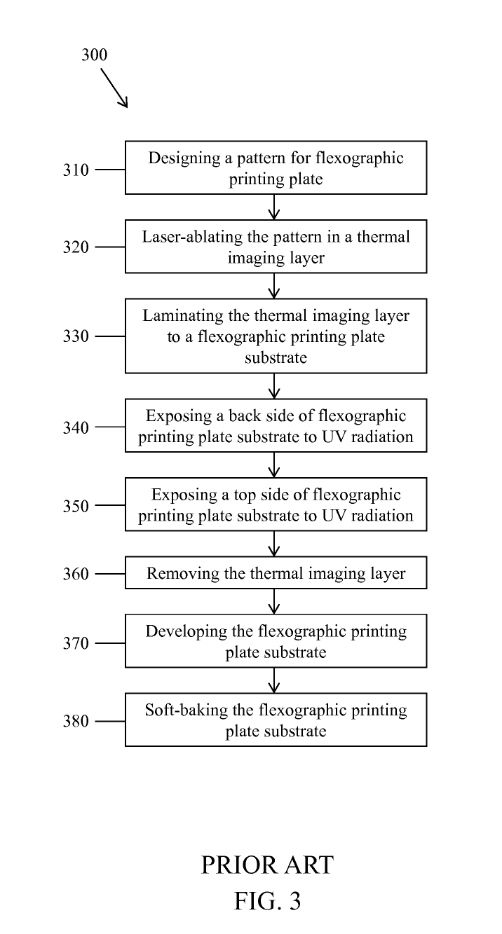

FIG. 3 shows a method of manufacturing a conventional flexographic printing plate. In step 310, a patterned design may be designed in a software application, such as a computer-aided drafting (“CAD”) software application. The patterned design includes a pattern to be patterned into a flexographic printing plate that, when used as part of a flexographic printing process, prints a corresponding patterned design on a substrate. In step 320, the patterned design is laser-ablated into a thermal imaging layer. The thermal imaging layer includes a PET layer covered by a laser-ablation resist material. The laser-ablation process ablates portions of the laser-ablation resist material in a pattern corresponding to the patterned design, but does not extend into the PET layer. After laser-ablation, the thermal imagining layer includes the PET layer and remaining portions of the laser-ablation resist material, where the exposed portions of the PET layer correspond to the patterned design.

In step 330, the thermal imaging layer is laminated to a flexographic printing plate substrate. The flexographic printing plate includes a PET base layer covered by a photopolymer material. The PET side of the thermal imaging layer is laminated to a top side, or photopolymer side, of the flexographic printing plate substrate. In step 340, a back side of the flexographic printing plate substrate is exposed to ultraviolet (“UV”) radiation. The back side, or PET side, of the flexographic printing plate is exposed to UV-A radiation for a period of time in a range between approximately 5 seconds and approximately 3 minutes. In step 350, the top side of the flexographic printing plate substrate is exposed to UV radiation. The top side of the flexographic printing plate substrate, through the thermal imaging layer, is exposed to UV-A radiation for a period of time in a range between approximately 5 minutes to approximately 30 minutes. In step 360, the thermal imaging layer is removed from the flexographic printing plate substrate.

In step 370, the flexographic printing plate substrate is developed. The flexographic printing plate substrate is developed with a washout liquid that removes the unexposed portions of the photopolymer material and leaves the UV-exposed portions of the photopolymer material corresponding to the patterned design. In step 380, the flexographic printing plate substrate is soft-baked at a temperature in a range between approximately 50 degrees Celsius and approximately 60 degrees Celsius for a period of time in a range between approximately 1 hour and approximately 3 hours.

After soft-baking, the conventional flexographic printing plate is mounted to a printing plate cylinder for use in a flexographic printing process. However, the conventional flexographic printing plate is not suitable for printing fine lines and features. A surface of the flexographic printing plate substrate is not perfectly smooth and has a roughness that varies over the surface. When the thermal imaging layer is laminated to the flexographic printing plate substrate, the lamination is uneven because of the variable roughness of the surface of the substrate. During UV exposure, the uneven lamination can result in unintentionally exposed areas, unintentionally unexposed areas, over exposed areas, and under exposed areas of the flexographic printing plate substrate. The improper exposure can result in non-uniform lines and features as well as undesired shorts and breaks when printing the patterned design on a substrate with the flexographic printing plate.

The resolution of the thermal imaging layer is limited by the type of laser used to laser-ablate the thermal imaging layer. The laser typically used has a maximum resolution of 2400 dots-per-inch (“DPI”) that limits the resolution of the thermal imaging layer to lines or features having a width of 10 micrometers or more. Other lasers, providing higher resolution, are controlled by the government because of their use in the currency printing process. In addition, the resolution of the thermal imaging layer is limited by the laser generated patterns. The thermal imaging system uses a laser that generates square pixels that are 10.5 micrometers or more in width on the thermal imaging layer. The square pixels are arranged in a series to form one or more lines or other features on the thermal imaging layer and ultimately the photopolymer of the flexographic printing plate substrate. As such, the widths of lines or features generated are limited by the pixel resolution of the laser itself. In addition, each pixel-to-pixel joint of the pixelated pattern forms a wall between pixels on the flexographic printing plate. The walls between pixels on the flexographic printing plate contribute to non-uniform line widths when printing with the flexographic printing plate. The walls may be susceptible to, for example, variation, necking, beading, or breaking The susceptibility of walls to these kinds of issues increases as the pixel size is decreased. Thus, conventional flexographic printing plates can only print lines or features having a width of 10 micrometers or more and they still suffer from non-uniformity due to the pixelated nature of the patterns.

In one or more embodiments of the present invention, a method of manufacturing a high-resolution flexographic printing plate with a photomask produces a flexographic printing plate capable of printing fine lines or features. In contrast to flexographic printing plates manufactured using thermal imaging layers, the high-resolution flexographic printing plate includes fine lines or features that are continuous with no issues associated with pixelization associated with the use of a thermal imaging layer.

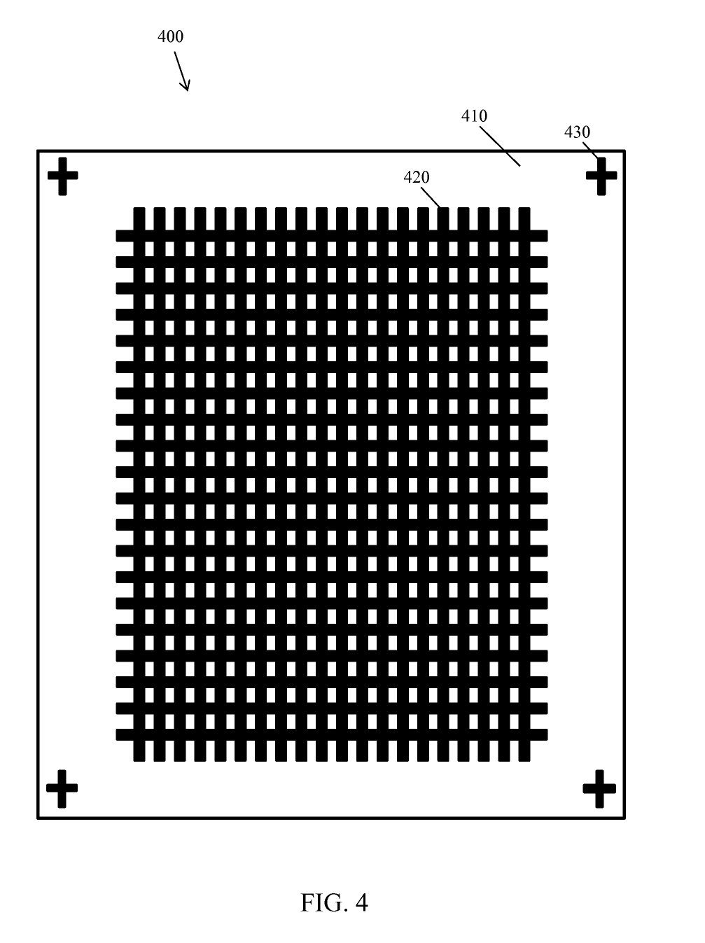

FIG. 4 shows a top-view of a photomask in accordance with one or more embodiments of the present invention. Photomask 400 includes a photomask substrate 410 composed of glass or quartz (not independently illustrated) that may be covered on one side by an UV-opaque layer (not independently illustrated). A patterned design 420 is etched into the opaque layer of photomask substrate 410, leaving photomask substrate 410 partially covered by the opaque layer (not independently illustrated) and partially exposed in patterned design area 420 where the opaque layer has been etched away. In certain embodiments, photomask 400 patterned design 420 may include one or more lines or features having a width less than 10 micrometers. In other embodiments, photomask 400 patterned design 420 may include one or more lines or features having a width less than 5 micrometers. In still other embodiments, photomask 400 patterned design 420 may include one or more lines or features having a width less than 1 micrometer. In certain embodiments, patterned design 420 may be any pattern to be patterned into a flexographic printing plate. For example, patterned design 420 may include a pattern corresponding to a conductive pattern design (100 of FIG. 1) of micro-mesh conductors for use in manufacturing a touch sensor. In touch sensor applications, to reduce the visibility of the micro-mesh of conductors, lines or features having a width of 3 micrometers or less may be used. One of ordinary skill in the art will recognize that patterned design 420 may vary based on an application. Photomask 400 may include one or more alignment marks 430 to help align photomask 400 with a substrate (not shown).

Photomask 400 may be used as part of a lithographic process. Lithography is a patterning process in which a patterned design 420 may be transferred from a photomask 400 to a photoresist material (not shown) as part of a substrate (not shown) patterning process. Photomask 400 includes an opaque surface (not independently illustrated) with a plurality of open or radiation transparent portions that form patterned design 420 to be transferred. Radiation incident on photomask 400 passes through the open portions of photomask 400 to expose portions of the photoresist material (not shown) in a pattern 420 corresponding to the open portions of photomask 400. Radiation incident on the opaque surface of photomask 400 does not pass through photomask 400 and the photoresist material (not shown) remains unexposed in a pattern corresponding to the opaque surface of photomask 400.

In operation, photomask 400 may be used with positive photoresist or negative photoresist depending on an application. If positive photoresist material (not shown) is used, the exposed portions of the photoresist material (not shown) are removed by a photoresist developer, while the unexposed portions of the photoresist material (not shown) remain on the substrate (not shown). If negative photoresist material (not shown) is used, the exposed portions of the photoresist material (not shown) remain on the substrate (not shown), while the unexposed portions of the photoresist material (not shown) are removed by a photoresist developer. After development, one or more physically exposed portions of the substrate (not shown) may be patterned by an etching process, while physically unexposed portions of the substrate (not shown) remain covered by the photoresist material (not shown). After etching, remaining portions of the photoresist material (not shown) are removed. In operation, photomask 400 may be used to replicate a patterned design 420 on a plurality of substrates (not shown) as part of the substrate patterning process. Depending on the type of photoresist used (positive or negative) and the type of photomask used (positive or negative), photomask 400 may be used to replicate a positive image of photomask 400 patterned design 420 or a negative image of photomask 400 patterned design 420 on one or more substrates (not shown).

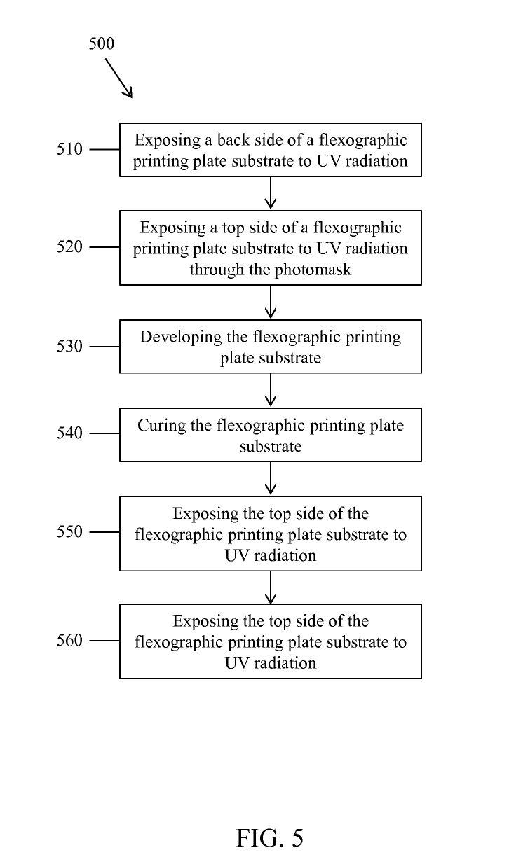

Photomask 400 may be provided by a commercial vendor of photomasks. The commercial vendors typically provide photomasks for lithographic processes, for example, semiconductor patterning. However, a photomask 400 may be configured for use in the manufacture of a high-resolution flexographic printing plate. The patterned design 420 may be designed in a CAD software application and exported to a file format for transfer to the commercial vendor of photomasks. The patterned design 420 may include a pattern that is patterned into photomask 400 for use in patterning a high-resolution flexographic printing plate (not shown) as discussed with respect to FIG. 5.

FIG. 5 shows a method of manufacturing a high-resolution flexographic printing plate with a photomask in accordance with one or more embodiments of the present invention. A flexographic printing plate substrate may be composed of a PET base layer covered by an image-able photopolymer material. One of ordinary skill in the art will recognize that the composition of the flexographic printing plate substrate may vary in accordance with one or more embodiments of the present invention. In certain embodiments, the flexographic printing plate substrate may have a length and a width suitable for mounting to an 18 inch printing plate cylinder. In other embodiments, the flexographic printing plate substrate may have a length and a width suitable for mounting to a 24 inch printing plate cylinder. One of ordinary skill in the art will recognize that the length and the width of the flexographic printing plate substrate may vary based on an application in accordance with one or more embodiments of the present invention. In certain embodiments, the PET base layer of the flexographic printing plate substrate may have a thickness in a range between approximately 75 micrometers and approximately 200 micrometers. The photopolymer material may have a thickness in a range between approximately 0.5 millimeters and 1.5 millimeters. One of ordinary skill in the art will recognize that the thickness PET layer and photopolymer layer may vary in accordance with one or more embodiments of the present invention.

In step 510, a back side of the flexographic printing plate substrate may be exposed to a first UV radiation. In certain embodiments, the back side of the flexographic printing plate substrate may be exposed to UV-A radiation with a wavelength in a range between approximately 315 nanometers and approximately 400 nanometers. The UV-A exposure time may be in a range between approximately 5 seconds and approximately 50 seconds depending on a thickness of the flexographic printing plate substrate and a desired relief depth of a patterned portion of the photopolymer material on the flexographic printing plate substrate.

In step 520, a top side of the flexographic printing plate substrate may be exposed to a second UV radiation through a photomask (e.g., 400 of FIG. 4). In certain embodiments, the top side of the flexographic printing plate substrate may be exposed through the photomask to UV-A radiation with a wavelength in a range between approximately 315 nanometers and approximately 400 nanometers. The UV-A exposure time may be in a range between approximately 300 seconds and approximately 1200 seconds depending on the thickness of the flexographic printing plate substrate and the desired relief depth. Portions of the photopolymer material of the flexographic printing plate substrate may be exposed to UV radiation through the patterned design area of the photomask. One of ordinary skill in the art will recognize that the patterned design may vary based on an application in accordance with one or more embodiments of the present invention.

In step 530, the flexographic printing plate substrate may be developed. After top side UV radiation exposure, portions of the photopolymer material of the flexographic printing plate substrate corresponding to the patterned design of the photomask are exposed to UV radiation, while portions of the photopolymer material remain unexposed. A washout fluid may be used to remove unexposed areas of the photopolymer material, while exposed portions of the photopolymer material remain. After development, the flexographic printing plate substrate includes the PET layer and exposed photopolymer material corresponding to the patterned design of the photomask.

In step 540, the flexographic printing plate substrate may be cured. In certain embodiments, the flexographic printing plate may be soft-baked at a temperature in a range between approximately 50 degrees Celsius and approximately 60 degrees Celsius for a period of time in a range between approximately 45 minutes and approximately 1 hour. After development with the washout fluid, the flexographic printing plate substrate may be wet and pliable. Soft-baking may increase the sturdiness and may reduce the swelling of the flexographic printing plate. In other embodiments, the flexographic printing plate may be cured by leaving the flexographic printing plate at room temperature for approximately 8 hours. One of ordinary skill in the art will recognize that the flexographic printing plate may be cured in different ways in accordance with one or more embodiments of the present invention.

In step 550, the top side of the flexographic printing plate substrate may be exposed to a third UV radiation. In certain embodiments, the top side of the flexographic printing plate substrate may be exposed UV-A radiation with a wavelength in a range between approximately 315 nanometers and approximately 400 nanometers. The UV-A exposure time may be in a range between approximately 1 minute and approximately 3 minutes. The UV-A radiation may polymerize remaining partially polymerized portions of the photopolymer material on the flexographic printing plate substrate. In this way, portions of UV exposed photopolymer material remaining on the flexographic printing plate substrate in a pattern corresponding to the patterned design of the photomask may be further polymerized. In certain embodiments, UV radiation of step 550 may not be necessary depending on an application.

In step 560, the top side of the flexographic printing plate substrate may be exposed to a fourth UV radiation. In certain embodiments, the top side of the flexographic printing plate substrate may be exposed UV-C radiation with a wavelength in a range between approximately 190 nanometers and approximately 280 nanometers. The UV-C exposure time may be in a range between approximately 1 minute and approximately 20 minutes. The UV-C radiation may remove any remaining volatile organic compounds on the surface of the flexographic printing plate in preparation for mounting to a printing plate cylinder. In certain embodiments, UV radiation of step 560 may not be necessary depending on an application.

After exposure, the flexographic printing plate (260 of FIG. 2) may be mounted to a printing plate cylinder (250 of FIG. 2) for use as part of a flexographic printing system (200 of FIG. 2). Because the method of manufacturing the flexographic printing plate does not use a thermal imaging layer, there is no limitation imposed by the resolution constraints of commercially available lasers. In addition, because the method does not use a thermal imaging layer, there is no lamination step and no corresponding issues that arise from uneven lamination of the thermal imaging layer to the flexographic printing plate substrate. Finally, because the method does not use a thermal imaging layer, there are no issues that arise from the pixelated patterns generated by the laser used to form the thermal imaging layer.

Advantages of one or more embodiments of the present invention may include one or more of the following:

In one or more embodiments of the present invention, a method of manufacturing a high-resolution flexographic printing plate with a photomask may produce continuous lines or features that are free from pixelization or any negative consequences of pixelization that occurs from using thermal imaging layers.

In one or more embodiments of the present invention, a method of manufacturing a high-resolution flexographic printing plate with a photomask may produce a flexographic printing plate capable of printing lines or features having a width of 1 micrometer of less.

In one or more embodiments of the present invention, a method of manufacturing a high-resolution flexographic printing plate with a photomask may produce a flexographic printing plate capable of printing lines or features having a width of 5 micrometers of less.

In one or more embodiments of the present invention, a method of manufacturing a high-resolution flexographic printing plate with a photomask may produce a flexographic printing plate capable of printing lines or features having a width of 10 micrometers of less.

In one or more embodiments of the present invention, a method of manufacturing a high-resolution flexographic printing plate with a photomask does not use a thermal imaging layer. Because the method does not use the thermal imaging layer, there is no need to laminate the thermal imaging layer to the flexographic printing plate substrate.

In one or more embodiments of the present invention, a method of manufacturing a high-resolution flexographic printing plate with a photomask does not require a thermal imaging system.

In one or more embodiments of the present invention, a method of manufacturing a high-resolution flexographic printing plate with a photomask reduces flexographic printing plate manufacturing costs.

In one or more embodiments of the present invention, a method of manufacturing a high-resolution flexographic printing plate with a photomask simplifies flexographic printing plate manufacturing processes.

In one or more embodiments of the present invention, a method of manufacturing a high-resolution flexographic printing plate with a photomask improves flexographic printing plate manufacturing efficiency.

In one or more embodiments of the present invention, a method of manufacturing a high-resolution flexographic printing plate with a photomask reduces flexographic printing plate manufacturing waste.

In one or more embodiments of the present invention, a method of manufacturing a high-resolution flexographic printing plate with a photomask may produce a flexographic printing plate with smaller lines or features than a conventional method of manufacturing a flexographic printing plate.

In one or more embodiments of the present invention, a method of manufacturing a high-resolution flexographic printing plate with a photomask is less expensive than a conventional method of manufacturing a flexographic printing plate.

In one or more embodiments of the present invention, a method of manufacturing a high-resolution flexographic printing plate with a photomask is less complicated than a conventional method of manufacturing a flexographic printing plate.

In one or more embodiments of the present invention, a method of manufacturing a high-resolution flexographic printing plate with a photomask is more efficient than a conventional method of manufacturing a flexographic printing plate

In one or more embodiments of the present invention, a method of manufacturing a high-resolution flexographic printing plate with a photomask produces less waste than a conventional method of manufacturing a flexographic printing plate

In one or more embodiments of the present invention, a method of manufacturing a high-resolution flexographic printing plate with a photomask produces a flexographic printing plate compatible with flexographic printing processes.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A method of manufacturing a high-resolution flexographic printing plate comprising:
exposing a back side of a flexographic printing plate substrate to a first UV radiation;
exposing a top side of the flexographic printing plate substrate to a second UV radiation through a photomask comprising a patterned design;
developing the flexographic printing plate substrate; and
curing the flexographic printing plate substrate.

2. The method of claim 1, further comprising:
exposing the top side of the flexographic printing plate substrate to a third UV radiation; and
exposing the top side of the flexographic printing plate substrate to a fourth UV radiation.

3. The method of claim 1, wherein the flexographic printing plate substrate comprises a polyethylene terephthalate base layer covered by a photopolymer material.

4. The method of claim 1, wherein the first UV radiation comprises UV-A radiation with an exposure time in a range between approximately 5 seconds and approximately 50 seconds.

5. The method of claim 1, wherein the second UV radiation comprises UV-A radiation with an exposure time in a range between approximately 300 seconds and approximately 1200 seconds.

6. The method of claim 1, wherein the patterned design comprises one or more lines having a width less than 1 micrometer.

7. The method of claim 1, wherein the patterned design comprises one or more lines having a width less than 5 micrometers.

8. The method of claim 1, wherein the patterned design comprises one or more lines having a width less than 10 micrometers.

9. The method of claim 1, wherein curing comprises soft-baking the flexographic printing plate substrate at a temperature in a range between approximately 50 degrees Celsius and approximately 60 degrees Celsius.

10. The method of claim 1, wherein curing comprises curing the flexographic printing plate substrate at room temperature.

11. The method of claim 2, wherein the third UV radiation comprises UV-A radiation with an exposure time in a range between approximately 1 minute and approximately 3 minutes.

12. The method of claim 2, wherein the fourth UV radiation comprises UV-C radiation with an exposure time in a range between approximately 1 minute and approximately 20 minutes.

13. The method of claim 1, wherein the high-resolution flexographic printing plate comprises embossing patterns corresponding to the patterned design of the photomask.

14. The method of claim 13, wherein the embossing patterns comprise one or more lines having a width less than 1 micrometer.

15. The method of claim 13, wherein the embossing patterns comprise one or more lines having a width less than 5 micrometers.

16. The method of claim 13, wherein the embossing patterns comprise one or more lines having a width less than 10 micrometer.

17. A flexographic printing system comprising:
an ink roll;
an anilox roll;
a printing plate cylinder;
a high-resolution flexographic printing plate disposed on the printing plate cylinder; and
an impression cylinder,
wherein the flexographic printing plate comprises embossing patterns corresponding to a patterned design, and
wherein the embossing patterns are patterned into the flexographic printing plate using a photomask.

18. The flexographic printing system of claim 17, wherein the embossing patterns comprise one or more lines having a width less than 1 micrometer.

19. The flexographic printing system of claim 17, wherein the embossing patterns comprise one or more lines having a width less than 5 micrometer.

20. The flexographic printing system of claim 17, wherein the embossing patterns comprise one or more lines having a width less than 10 micrometer.
